(19) United States
(12) Patent Application Publication
(10) Pub. No.: US 2008/0231258 A1
(43) Pub. Date: Sep. 25, 2008

(54) STIFFENING CONNECTOR AND PROBE CARD ASSEMBLY INCORPORATING SAME

(75) Inventors: Eric D. Hobbs, Livermore, CA (US); Gaetan L. Mathieu, Varennes (CA)

Correspondence Address: MOSER IP LAW GROUP / FORMFACTOR, INC., 1030 BROAD STREET, 2ND FLOOR, SHREWSBURY, NJ, 07702, US

(73) Assignee: FORMFACTOR, INC., Livermore, CA (US)

(21) Appl. No.: 11/690,139

(22) Filed: Mar. 23, 2007

(51) Int. Cl. G01R 1/06

(52) U.S. Cl. 324/149

(57) ABSTRACT

A stiffening connector assembly and methods of use are provided herein. In some embodiments a stiffening connector assembly includes a connector configured to be coupled to a substrate; and a mechanism coupled to the connector and configured to restrict rotational movement of the connector with respect to the substrate when coupled thereto. The mechanism may further provide a lateral degree of freedom of movement in a direction substantially parallel to the substrate.

### BACKGROUND OF THE INVENTION

1. Field of the Invention

Embodiments of the present invention generally relate to testing of partially or fully completed semiconductor devices and, more particularly, to stiffener assemblies for use in connection with apparatus for testing such devices.

2. Description of the Related Art

When testing partially or fully completed semiconductor devices formed on a semiconductor substrate, such as integrated circuits and the like, a contact element is typically brought into contact with the device to be tested—also referred to as a device under test (or DUT). The contact element is typically part of a probe card assembly or other similar device coupled to a test mechanism that provides electrical signals to terminals on the DUT in accordance with a predetermined testing protocol.

In order to sufficiently and accurately contact selected terminals of the DUT during a particular testing protocol, the contact elements disposed on the probe card assembly must be brought into contact with the terminals of the DUT and must maintain alignment therewith. However, various forces applied to the probe card assembly may cause the assembly to deflect in a manner that may cause misalignment of the contact elements. Accordingly, the probe card assembly generally includes stiffening members and/or assemblies designed to minimize such deflection of the probe card assembly.

However, even with such stiffening members, undesirable deflection of the probe card assembly may still occur due to forces imposed upon the probe card assembly by connectors disposed about a peripheral edge of the probe card assembly. For Example, FIGS. 1A-B depict a probe card assembly 100 having a conventional connector 104 coupled to a substrate 102. The connector 104 typically comprises a male portion 108 that may be coupled to the substrate 102 and a female portion 106 that is selectively inserted into the male portion 108 to make electrical connection therewith. A stiffener 110 is provided to stiffen an inner portion 120 of the substrate 102, while the connector 104 is disposed on an outer portion 122 of the substrate 102 (e.g., disposed radially outwards of the stiffener 110).

As shown in FIG. 1A, the substrate 102 is substantially flat, or planar, prior to insertion of the female portion 106 of the connector 104 into the male portion 108 of the connector 104. However, even after the connector 104 is engaged (e.g., after the female portion 106 is inserted into the male portion 108) a downward alignment force remains applied, thereby imposing a downward force upon the substrate 102. As shown in FIG. 1B, this downward force (F) may be sufficient to cause the substrate 102 to deflect, or bend in regions outward of the stiffener 110. This deflection of the substrate 102 may interfere with the alignment of the substrate 102, and/or the alignment of a probe substrate and contact elements disposed therebeneath (not shown), with terminals of the DUT during testing. Moreover, such deflection of the substrate 102 restricts use of probe substrates that may extend into the outer region 122 of the substrate 102, thereby undesirably limiting the usefulness of the probe card assembly 100 to test larger DUTs or arrays of DUTs.

Even with the utilization of so-called zero insertion force (ZIF) connectors, the relatively small forces utilized to make these connections are multiplied by the number of connectors applied about the peripheral of the substrate, thereby still applying considerable forces to the probe card assembly. In addition, the number and density of connectors disposed about the edge of the probe card assembly may further limit the space available to utilize additional components to stiffen the probe card assembly.

Therefore, there is a need for an improved stiffening assembly.

### SUMMARY OF THE INVENTION

A stiffening connector assembly and methods of use are provided herein. In some embodiments a stiffening connector assembly includes a connector configured to be coupled to a substrate; and a mechanism coupled to the connector and configured to restrict rotational movement of the connector with respect to the substrate when coupled thereto. The mechanism may further provide a lateral degree of freedom of movement in a direction substantially parallel to the substrate.

In some embodiments of the invention, a probe card assembly having a stiffening connector assembly is provided. In some embodiments a probe card assembly includes a substrate having an upper surface and an opposing lower surface; a stiffener coupled to the upper surface of the substrate on an inner portion thereof; a connector coupled to the upper surface of the substrate on an outer portion thereof; and a mechanism coupling the connector to at least one of the substrate or the stiffener, the mechanism restricting rotational movement of the connector. The mechanism may further provide a lateral degree of freedom of movement in a direction substantially parallel to the substrate.

In some embodiments of the invention, a method for using a probe card assembly having a stiffening connector assembly is provided. In some embodiments a method of using a probe card assembly includes providing a probe card assembly having a substrate and a plurality of contact elements; and coupling a plurality of connectors thereto along an outer portion of an upper surface of the substrate, the connectors further coupled to a mechanism configured to restrict rotational movement of each of the connectors. The mechanism may further provide a lateral degree of freedom of movement in a direction substantially parallel to the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A and 1B depict a probe card assembly having conventional ZIF connectors engaged therewith.

FIG. 2 depicts a stiffening connector in accordance with some embodiments of the present invention.

FIG. 3 depicts a connector in accordance with some embodiments of the invention.

FIG. 4 depicts a connector in accordance with some embodiments of the invention.

FIG. 5 depicts a connector in accordance with some embodiments of the invention.

FIG. 6 depicts a connector in accordance with other embodiments of the invention.

FIG. 7 depicts stiffening mechanisms in accordance with some embodiments of the invention.

FIG. 8 depicts a probe card assembly in accordance with some embodiments of the invention.

Where possible, identical reference numerals are used herein to designate identical elements that are common to the figures. The images used in the drawings are simplified for illustrative purposes and are not necessarily depicted to scale.

### DETAILED DESCRIPTION

The present invention provides embodiments of stiffening connector assemblies and probe card assemblies incorporating the same. Methods of use of the stiffening connector assembly and the probe card assembly are further provided. The stiffening connector assembly advantageously provides improved stiffening of a substrate in use with a probe card assembly, and, more particularly, may provide improved stiffening of outer portions of the substrate.

FIG. 2 depicts a probe card assembly 200 in accordance with some embodiments of the present invention. As depicted in FIG. 2, the probe card assembly 200 can generally comprise a substrate 201 having a stiffening connector assembly 203. The stiffening connector assembly 203 may comprise at least one of a connector 204, a mechanism 202, and a stiffener 201. The connector 204 may be coupled to the stiffener 210 and/or the substrate 201 by the mechanism 202. Although the example depicted in FIG. 2 shows the connector 204 as having a female portion 206 interfacing with a male portion 208 (e.g., a ZIF connector, or the like), it is contemplated that any suitable connector may be modified in accordance with the teachings disclosed herein to provide a stiffening connector assembly. In addition, although the connector 204, mechanism 202, and stiffener 201 are described separately herein, it is contemplated that one or more of these components may be combined into single elements providing at least the function described herein. For example, the stiffener 201, connector 204 (or a portion thereof), and mechanism 202 may be a single element, or the connector 204 and mechanism 202 may be a single element, or other combinations (including as a part or subpart of each or any of the above-described components).

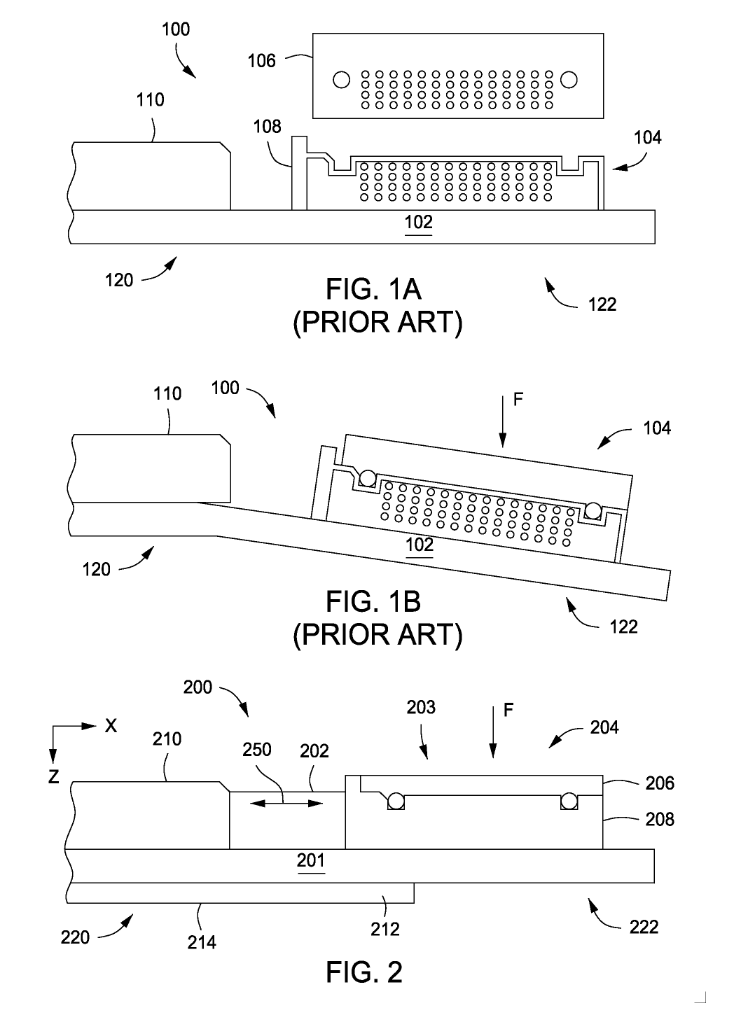

The stiffening connector assembly 203 generally restricts rotational movement of the connector 204 with respect to the substrate 201 (e.g., maintains planar alignment when a force, F, is applied) and may facilitate a lateral degree of freedom of movement in a direction substantially parallel to the substrate 201 (e.g., allows lateral movement of as indicated by arrow 250). As such, the stiffening connector assembly 203 further advantageously restricts radial deflection of the substrate 201, such that the inner portion 220 of the substrate 201 and the outer portion 222 of the substrate 201 remain substantially coplanar, thereby facilitating use of a probe substrate 212 that may extend from the inner portion 220 to the outer portion 222. Thus, as compared to conventional probe card assemblies, such as discussed above with respect to FIGS. 1A-B, the probe card assembly 200 utilizing the inventive stiffening connector assembly 203 can facilitate greater ease of maintaining planarity and/or alignment of contact elements disposed on a probe surface 214 of the probe card assembly 200 with terminals of a DUT or array of DUTs during use. The inventive stiffening connector assembly 203 can further facilitate use of larger probe substrates 210 that may extend beneath the outer portion 222 of the substrate 201 without interference from any bending of the substrate 201.

Typically, an insertion force of about 5 pounds is applied to make connections utilizing some connectors. Accordingly, in some embodiments, the stiffening connector assembly 203 may be configured to withstand such forces. However, the stiffening connector assembly 203 may be configured to withstand greater or lesser forces as desired for a particular application. As such, the stiffening connector assembly 203 components, such as the connector 204, the mechanism 202, and/or the stiffener 210 may be at least partially fabricated out of metals, reinforced plastics, or others suitable materials (such as ceramics composites, and the like).

In some embodiments, the mechanism 202 may comprise any suitable mechanism for restricting the radial motion of the connector 204 with respect to a substrate 201 while facilitating a lateral degree of freedom of movement of the connector 204 in a direction substantially parallel to the substrate 201. Such a mechanism facilitates operation of a probe card assembly wherein rotational forces may develop within the probe card assembly 200 due to, for example, heating and/or cooling of the probe card assembly 200 (or components thereof), thereby causing different quantities of expansion and/or contraction of the substrate 102 and any components coupled thereto (e.g., at least the connector 204, the stiffener 210, and the mechanism 202.). For example, in embodiments where the connector 204 is fixedly coupled to the substrate 201, the mechanism 202 may facilitate lateral movement between the connector 204 and the stiffener 210. In embodiments where the connector 204 is movably coupled to the substrate 201, the mechanism 202 may allow lateral movement between the connector 204 and the substrate 201.

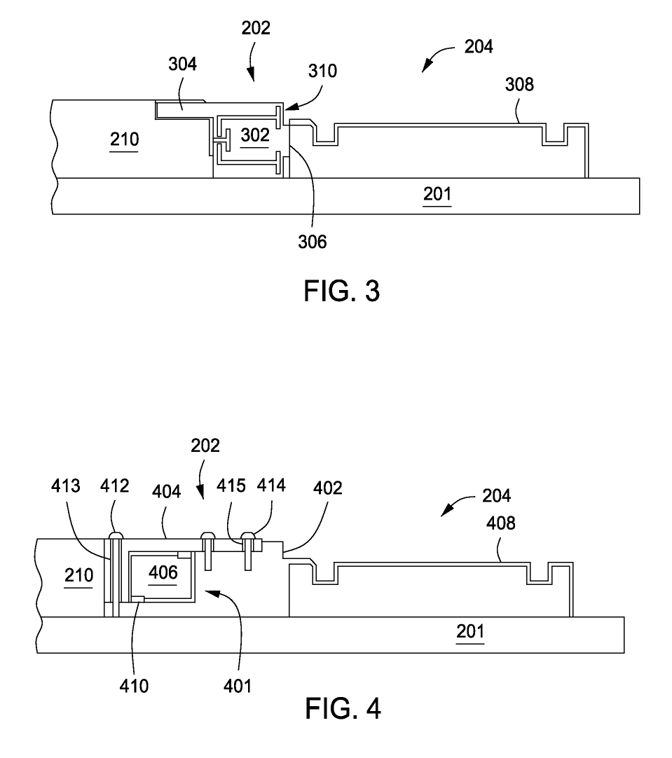

A number of non-limiting examples of various embodiments of the mechanism 202 are provided herein and described below with respect to FIGS. 3 through 6. As can be seen from the examples, the mechanism 202 may comprise one or more flexures, slip structures, or the like, or combinations thereof to restrict rotation while facilitating or allowing radial, or lateral movement. As FIGS. 3-6 illustratively depict a few non-limiting examples of certain components of the mechanism 202, it is contemplated that other structures, features, or combinations of elements may be provided to obtain a desired stiffening connector assembly in accordance with the inventive apparatus and teachings disclosed herein.

FIG. 3 depicts a non-limiting example of a mechanism 202 comprising a body 302 having a plurality of flexures 310 according to some embodiments of the invention. The body 302 may include a first portion 304 that may be coupled to the stiffener 210 and a second portion 306 that may be coupled to the connector 204 (or a portion thereof, such as a lower portion 308 of the connector 204). The first and second portions 304, 306 may be respectively coupled to the stiffener 210 and the connector 204 by any suitable means, such as by bonding, bolting, clamping, or the like. Alternatively, one or both of the first and second portions 304, 306 may be respectively integrally formed in the stiffener 210 or the connector 204.

The plurality of flexures 310 may be formed integrally in the body 302 of the mechanism 202. The plurality of flexures 310 may be aligned orthogonally to the substrate 201 to provide stiffness in a direction orthogonal to the substrate 201, thereby restricting rotation of the substrate 201, while allowing movement of the first portion 304 and the second portion 306 of the mechanism 202 with respect to each other in a direction substantially parallel to the substrate 201.

FIG. 4 depicts a non-limiting example of a mechanism 202 having a slip structure 401 in accordance with some embodiments of the present invention. The slip structure 401 may include a first portion 404 may be coupled to the stiffener 210 and a second portion 402 that may be coupled to the connector 204 (or a portion thereof, such as lower portion 408 of the connector 204). The first and second portions 402, 404 may be respectively coupled to the stiffener 210 and the connector 204 by any suitable means, such as described above with respect to FIG. 3. Alternatively, one or both of the first and second portions 402, 404 may be respectively integrally formed in the stiffener 210 or the connector 204.

The first and second portions 402, 404 of the slip structure 401 may be moveably coupled together to facilitate lateral motion of the connector 204 with respect to the stiffener 210 in a direction substantially parallel to the substrate 201. For example, in the embodiment depicted in FIG. 4, a screw 412 is used to couple the second portion 404 to the first portion 402 through a hole 413 formed in the second portion 404 and at least one screw 414 (2 screws 414 shown in FIG. 4) may extend through a hole 415 formed in the second portion 404 and coupled with the first portion 402. The holes 413, 415 formed in the second portion 404 may be oversized with respect to a shaft of the screws 412, 414 to facilitate lateral movement of the second portion 404. A spacer 406, and optionally, one or more pads 410, may be provided between the second portion 404 and the first portion 402 to facilitate reduction of friction between the first portion 402 and the second portion 404 as well as to provide additional rotational rigidity of the mechanism 202.

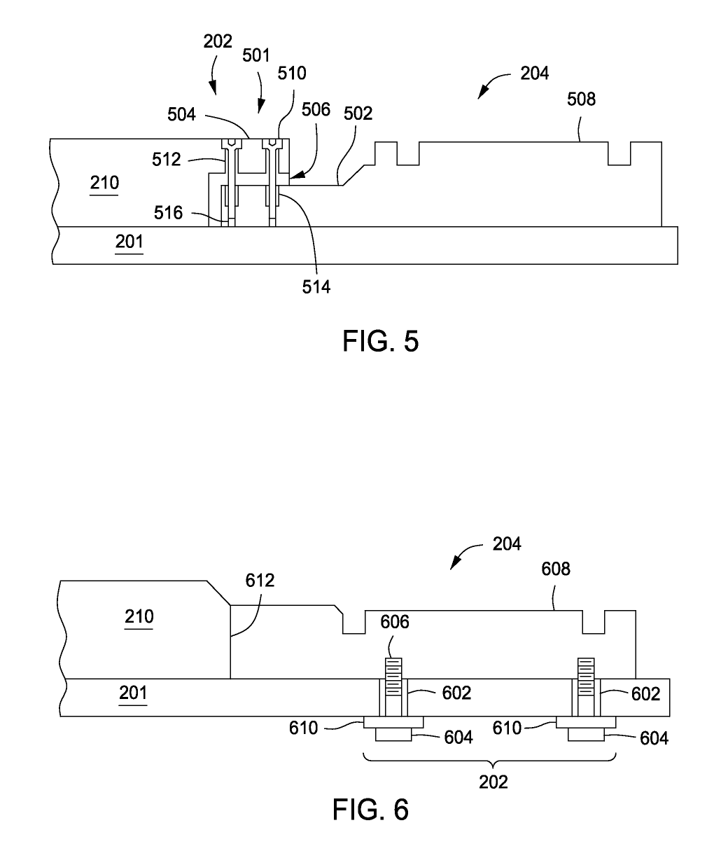

FIG. 5 depicts a non-limiting example of a mechanism 202 having a four-bar flexure 501 in accordance with some embodiments of the invention. The four-bar flexure 501 may include an extension 504 of the stiffener 210 moveably coupled by two screws 510 to an extension 502 of the connector 204 (or a portion thereof, such as lower portion 508). Alternatively, the extensions 502, 504 may be separate components respectively coupled to the connector 204 and the stiffener 210 by any suitable means, such as described above with respect to FIG. 3.

A gap 506 is provided between the extensions 502, 504. Holes 512 are formed in the extension 504 to allow the screws 510 to pass therethrough. Tapped holes 516 are provided in the extension 502 to receive screws 510. The two screws 510 and the two extensions 502, 504 operate together to form the four-bar flexure 501, thereby facilitating lateral movement of the connector 204 with respect to the stiffener 210 in a direction substantially parallel to the substrate 201 while remaining rotationally stiff. Optionally, holes 514 may be provided in the extension 502 to reduce stresses on the shafts of the screws 510 and to extend the range of motion of the four-bar flexure 501.

FIG. 6 depicts a non-limiting example of a mechanism 202 having a four-bar flexure 601 in accordance with some embodiments of the invention. The four-bar flexure 601 may include the substrate 201 and the connector 204 (or a lower portions thereof, such as lower portion 608) coupled together by two screws 604. The two screws 604, the substrate 201, and the connector 204 operate together to form the four-bar flexure 601, thereby facilitating lateral movement of the connector 204 with respect to the stiffener 210 in a direction substantially parallel to the substrate 201 while remaining rotationally stiff.

Oversized holes 602 may be formed in the substrate 201 to allow the screws 604 to pass therethrough and to engage with tapped holes 606 formed in the connector 204. Optionally, a washer 610 may be provided to facilitate alignment of the screws 604. The connector 204, or the lower portion 608 thereof, may be coupled to the stiffener 210 by a coupling 612, such as adhesive, bolts, clamps, or the like. Alternatively, the connector 204, or the lower portion 608 thereof, may be integrally formed in the stiffener 210.

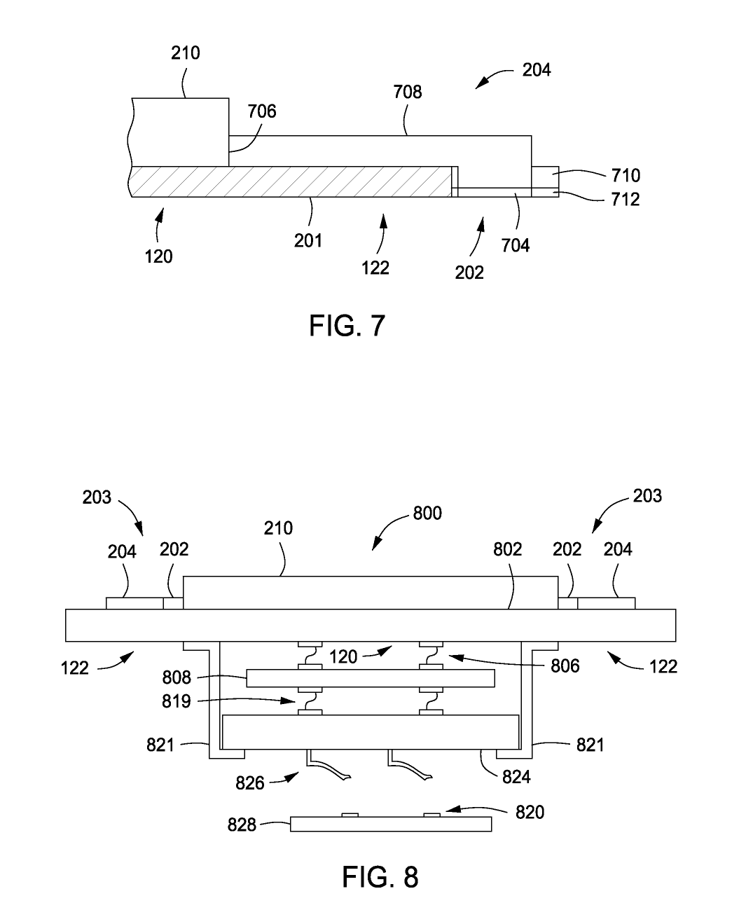

FIG. 7 depicts a non-limiting example of a mechanism 202 according to some embodiments of the invention. In the example of FIG. 7, the mechanism includes an extension 702 extending downward from the connector 204 (or a portion thereof, such as lower portion 708). The extension 702 may be integrally formed in the connector 204 or may be coupled thereto by any suitable means, such as by bonding, bolting, clamping, or the like. The extension 702 generally coincides with and passes through a slot 710 formed in the substrate 201. The extension 702 further includes a flange 704 disposed at a lower portion thereof and configured to interface with a corresponding ledge 712 formed in a lower portion of the slot 710. Interference between the flange 704 and the ledge 712 restricts bending, or rotational movement of the outer portion 122 of the substrate 201, without restricting lateral movement of the substrate 201 and connector 204 in a direction substantially parallel to the substrate 201.

The connector 204, or the lower portion 708 thereof, may be coupled to the stiffener 210 by a coupling 706, such as adhesive, bolts, clamps, or the like. Alternatively, the connector 204, or the lower portion 708 thereof, may be integrally formed in the stiffener 210.

FIG. 8 depicts a probe card assembly 800 utilizing a stiffening connector assembly 203 according to some embodiments of the present invention. The exemplary probe card assembly 800 illustrated in FIG. 8 can be used to test one or more electronic devices (represented by DUT 828). The DUT 828 can be any electronic device or devices to be tested. Non-limiting examples of a suitable DUT include one or more dies of an unsingulated semiconductor wafer, one or more semiconductor dies singulated from a wafer (packaged or unpackaged), an array of singulated semiconductor dies disposed in a carrier or other holding device, one or more multi-die electronics modules, one or more printed circuit boards, or any other type of electronic device or devices. The term DUT, as used herein, refers to one or a plurality of such electronic devices.

The probe card assembly 800 generally acts as an interface between a tester (not shown) and the DUT 828. The tester, which can be a computer or a computer system, typically controls testing of the DUT 828, for example, by generating test data to be input into the DUT 828, and receiving and evaluating response data generated by the DUT 828 in response to the test data. The probe card assembly 800 includes electrical connectors 204 configured to make electrical connections with a plurality of communications channels (not shown) from the tester. The electrical connectors 204 may be part of stiffening connector assembly 203 as described above. The probe card assembly 800 also includes one or more resilient contact elements 826 configured to be pressed against, and thus make temporary electrical connections with, one or more input and/or output terminals 820 of DUT 828. The resilient contact elements 826 are typically configured to correspond to the terminals 820 of the DUT 828 and may be arranged in one or more arrays having a desired geometry.

The probe card assembly 800 may include one or more substrates configured to support the connectors 204 and the resilient contact elements 826 and to provide electrical connections therebetween. The exemplary probe card assembly 800 shown in FIG. 8 has three such substrates, although in other implementations, the probe card assembly 800 can have more or fewer substrates. In the embodiment depicted in FIG. 8, the probe card assembly 800 includes a wiring substrate 802, an interposer substrate 808, and a probe substrate 824. The wiring substrate 802, the interposer substrate 808, and the probe substrate 824 can generally be made of any type of suitable material or materials, such as, without limitation, printed circuit boards, ceramics, organic or inorganic materials, and the like, or combinations thereof. For example, a plurality of connectors 204 (such as ZIF or other suitable connectors) may be coupled to an upper portion of the wiring substrate 802 in an outer region 822 thereof. As shown in FIG. 8, a stiffener 810 may be coupled to the wiring substrate 802 (which may be similar to the stiffener 210 and the substrate 201 described above). The stiffening connector assembly 203 may be utilized, as described above, to prevent flexing of the wiring substrate 802 upon application of connection and/or other forces and/or stresses (such as thermally induced stresses) to the connectors 204 or other components in the outer region 822 of the wiring substrate 802.

Electrically conductive paths (not shown) are typically provided from the connectors 204 through the various substrates to the resilient contact elements 826. For example, in the embodiment depicted in FIG. 8, electrically conductive paths (not shown) may be provided from the connectors 204 through the wiring substrate 802 to a plurality of electrically conductive spring interconnect structures 806. Other electrically conductive paths (not shown) may be provided from the spring interconnect structures 806 through the interposer substrate 808 to a plurality of electrically conductive spring interconnect structures 819. Still other electrically conductive paths (not shown) may further be provided from the spring interconnect structures 819 through the probe substrate 824 to the resilient contact elements 826. The electrically conductive paths through the wiring substrate 802, the interposer substrate 808, and the probe substrate 824 can comprise electrically conductive vias, traces, or the like, that may be disposed on, within, and/or through the wiring substrate 802, the interposer substrate 808, and the probe substrate 824.

The wiring substrate 802, the interposer substrate 808, and the probe substrate 824 may be held together by one or more brackets 821 and/or other suitable means (such as by bolts, screws, or other suitable fasteners). The configuration of the probe card assembly 800 shown in FIG. 8 is exemplary only and is simplified for ease of illustration and discussion and many variations, modifications, and additions are contemplated. For example, a probe card assembly may have fewer or more substrates (e.g., 802, 808, 824) than the probe card assembly 800 shown in FIG. 8. As another example, a probe card assembly may have more than one probe substrate (e.g., 824), and each such probe substrate may be independently adjustable. Other non-limiting examples of probe card assemblies with multiple probe substrates are disclosed in U.S. patent application Ser. No. 11/165,833, filed Jun. 24, 2005. Additional non-limiting examples of probe card assemblies are illustrated in U.S. Pat. No. 5,974,662, issued Nov. 2, 1999 and U.S. Pat. No. 6,509,751, issued Jan. 21, 2003, as well as in the aforementioned U.S. patent application Ser. No. 11/165,833. It is contemplated that various features of the probe card assemblies described in those patents and application may be implemented in the probe card assembly 800 shown in FIG. 8 and that the probe card assemblies described in the aforementioned patents and application may benefit from the use of the inventive stiffener assembly disclosed herein.

In operation, the resilient contact elements 826 are brought into contact with the terminals 820 of the DUT 828 by moving at least one of the DUT 828 or the probe card assembly 800. Typically, the DUT 828 can be disposed on a movable support disposed in the test system (not shown) that moves the DUT 828 into sufficient contact with the resilient contact elements 826 to provide reliable electrical contact with the terminals 820. The DUT 828 can then tested per a pre-determined protocol as contained in the memory of the tester. For example, the tester may generate power and test signals that are provided through the probe card assembly 800 to the DUT 828. Response signals generated by the DUT 828 in response to the test signals are similarly carried through the probe card assembly 800 to the tester, which may then analyze the response signals and determine whether the DUT 828 responded correctly to the test signals. Typically, the DUT 828 is tested at an elevated temperature (for example, up to 250 degrees Celsius for wafer level burn in). Accordingly, the probe card assembly 800 is typically preheated to a temperature equal to or within a given tolerance of the testing temperature. The stiffening connector assembly 203 of the present invention facilitates lateral movement of the components of the probe card assembly due to varying amounts of thermal expansion caused by the heating of the probe card assembly 800 during testing while restricting rotational movement of the substrate, thereby facilitating higher levels of precision in the placement of the contact elements 826.

Thus, embodiments of a stiffening connector assembly and a probe card assembly incorporating the same have been provided herein. The stiffening connector assembly comprises components restrict rotational movement while allowing lateral movement therebetween, thereby advantageously providing stiffening of a substrate in use with a probe card assembly while allowing lateral movement between probe card assembly components due to differing rates and/or amounts of thermal movement due to heating and/or cooling of the probe card assembly during testing.

While the foregoing is directed to embodiments of the present invention, other and further embodiments of the invention may be devised without departing from the basic scope thereof, and the scope thereof is determined by the claims that follow.

1. A stiffening connector assembly, comprising:
a connector configured to be coupled to a substrate; and
a mechanism coupled to the connector and configured to restrict rotational movement of the connector with respect to the substrate when coupled thereto.

2. The assembly of claim 1, wherein the mechanism further provides a lateral degree of freedom of movement in a direction substantially parallel to the substrate.

3. The assembly of claim 2, wherein the mechanism further comprises:
a slip structure for facilitating linear movement of the mechanism.

4. The assembly of claim 3, wherein the slip structure further comprises:
a first portion coupled to the connector; and
a second portion moveably coupled to the first portion.

5. The assembly of claim 4, further comprising:
a third portion disposed between the first and second portions, wherein one or more pads disposed between the third portion and at least one of the first and second portions provide a reduced friction contact area to facilitate linear movement of the first and second portions with respect to each other.

6. The assembly of claim 4, wherein the first and second portion are moveably coupled to each other by a plurality of screws.

7. The assembly of claim 1, wherein the mechanism further comprises at least one flexure.

8. The assembly of claim 7, wherein the at least one flexure is formed within a body of the mechanism.

9. The assembly of claim 7, wherein the mechanism further comprises:
a four-bar flexure.

10. The assembly of claim 9, wherein the four-bar flexure further comprises:
a first bar provided by one of the mechanism or the connector;
a second and a third bar provided by a pair of screws configured to be coupled to the first bar; and
wherein the fourth bar is provided by a substrate when the connector is coupled thereto.

11. The assembly of claim 10, wherein the first bar is provided by the mechanism.

12. The assembly of claim 10, wherein the first bar is provided by the connector.

13. The assembly of claim 1, wherein the mechanism comprises an extension disposed on an outer edge of the connector and having a flange formed proximate a lower edge of the extension and configured to interface with a lower portion of a substrate to prevent rotation thereof.

14. A probe card assembly, comprising:
a substrate having an upper surface and an opposing lower surface;
a stiffener coupled to the upper surface of the substrate on an inner portion thereof;
a connector coupled to the upper surface of the substrate on an outer portion thereof; and
a mechanism coupling the connector to at least one of the substrate or the stiffener, the mechanism restricting rotational movement of the connector.

15. The assembly of claim 14, wherein the mechanism further provides a lateral degree of freedom of movement in a direction substantially parallel to the substrate.

16. The assembly of claim 15, wherein the mechanism further comprises:
a slip structure for facilitating linear movement of the mechanism.

17. The assembly of claim 16, wherein the slip structure further comprises:
a first portion coupled to the connector; and
a second portion moveably coupled to the first portion.

18. The assembly of claim 17, further comprising:
a third portion disposed between the first and second portions, wherein one or more pads disposed between the third portion and at least one of the first and second portions provide a reduced friction contact area to facilitate linear movement of the first and second portions with respect to each other.

19. The assembly of claim 14, wherein the mechanism further comprises at least one flexure.

20. The assembly of claim 19, wherein the mechanism further comprises:
a four-bar flexure.

21. The assembly of claim 20, wherein the four-bar flexure further comprises:
a first bar provided by one of the mechanism or the connector;
a second and a third bar provided by a pair of screws configured to be coupled to the first bar; and
wherein the fourth bar is provided by a substrate when the connector is coupled thereto.

22. The assembly of claim 21, wherein the first bar is provided by the mechanism.

23. The assembly of claim 21, wherein the first bar is provided by the connector.

24. The assembly of claim 14, wherein the probe card assembly is configured to pass electrical signals to and from respective tips of the contact elements to a plurality of electrical connectors disposed on the probe card assembly.

25. The assembly of claim 14, further comprising a probe substrate coupled to the lower surface of the substrate.

26. The assembly of claim 25, wherein the probe substrate extends from the inner portion to the outer portion of the substrate.

27. The assembly of claim 14, wherein the substrate has a reduced flex when a connection force is applied to the connector, as compared to probe card assemblies not having the mechanism coupling the connector to the stiffener.

28. The assembly of claim 14, wherein the mechanism comprises an extension disposed on an outer edge of the connector and having a flange formed proximate a lower edge of the extension and configured to interface with a lower portion of a substrate to prevent rotation thereof.

29. A method of using a probe card assembly, comprising:
providing a probe card assembly having a substrate and a plurality of contact elements; and
coupling a plurality of connectors thereto along an outer portion of an upper surface of the substrate, the connectors further coupled to a mechanism configured to restrict rotational movement of each of the connectors.

30. The method of claim 29, wherein the mechanism further provides a lateral degree of freedom of movement in a direction substantially parallel to the substrate.

31. The method of claim 29, further comprising:
contacting at least one terminal of a device with respective tips of the plurality of contact elements; and
providing one or more electrical signals to the at least one terminal through the probe card assembly.

32. The method of claim 29, wherein the plurality of contact elements are disposed on a probe substrate coupled to a lower surface of the substrate, and further comprising:
planarizing the probe substrate prior to coupling the connectors to the substrate.

33. The method of claim 29, wherein the plurality of contact elements are disposed on a probe substrate coupled to a lower surface of the substrate and wherein the probe substrate extends from an inner portion of the substrate to the outer portion.
